(19) United States
(12) Patent Application Publication
(10) Pub. No.: US 2010/0302481 A1
(43) Pub. Date: Dec. 2, 2010

(54) ABSORBING WIRE GRID POLARIZER

(76) Inventors: Alexandra BAUM, Oxford (GB); Allan Evans, Oxford (GB); Lesley Anne Parry-Jones, Oxford (GB); Nathan James Smith, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/475,644

(22) Filed: Jun. 1, 2009

(51) Int. Cl. G02F 1/1335; G02B 5/30; C23C 14/00; B29D 11/00

(52) U.S. Cl. 349/96; 359/486; 204/192.26; 216/24

(57) ABSTRACT

A polarizer consisting of a wire grid that includes a plurality of wires aligned in parallel. From at least one side of the wire grid, the wire grid intrinsically mainly absorbs electromagnetic energy having a polarization direction parallel to the wires and mainly transmits electromagnetic energy having a polarization direction perpendicular to the wires.

### TECHNICAL FIELD

The present invention relates to a wire grid polarizer that shows light absorbing instead of light reflecting properties for the polarization direction that is perpendicular to the transmission axis of the polarizer. The absorbing properties concern one or either side of the wire grid. Such an absorbing wire grid polarizer enables the control of surface reflections from the element. It could, for example, be included with a liquid crystal display (LCD) for contrast enhancement or to facilitate integrated LCDs of reduced thickness.

### BACKGROUND OF THE INVENTION

A wire grid polarizer consists of an array of aligned metal structures as shown in FIG. 1. Such a grid of wires with spacing smaller than about half the wavelength is a reflective polarizer for electromagnetic waves of this wavelength. Progress in precision manufacturing has enabled wire grid polarizers at optical and even UV wavelengths. A typical design that acts as a polarizer in the visible wavelength range may have the following geometry related to FIG. 1: square profile metal wires 1 (typically Aluminum or Silver) with periodicity 4 of 100 nm, wire width 5 of 50 nm, wire thickness 6 of 100 nm. The wires are located on a substrate 2 and are embedded in a material 3, which may be air. FIG. 2 shows the optical performance of this example design with the aluminum wires on a glass substrate in air. The structure was simulated with the finite difference time domain (FDTD) software FDTD Solutions by Lumerical Solutions Incorporated. It can be seen that while the polarization direction perpendicular to the wires (p-polarization) is mainly transmitted, the polarization direction parallel to the wires (s-polarization) is mainly reflected. The ratio of transmitted p-polarized and s-polarized light is the extinction ratio of the polarizer (ER=Tp/Ts).

The reflective properties of wire grids are ideal for polarizing beam splitters. However, for certain applications, the reflections are unwanted, such as for example in polarizers for liquid crystal displays (LCDs).

In liquid crystal displays, the small thickness and durability at elevated temperatures of wire grid polarizers would allow their integration inside the liquid crystal cell, resulting in more compact devices and improved contrast. Iodine polarizers (iodine doped stretched polymer), which are conventionally used in LCDs, cannot be used in-cell because they are thick (typically ˜20 μm) and not robust against solvents and processing temperatures (˜200° C.). FIG. 3 shows the schematic of LCDs, comprising of a backlight unit 7, a first polarizer 8, a lower substrate 9 with pixel electrodes 10 to address the liquid crystal 11, a second substrate 14 with a common electrode 12 and color filters 13 and a second polarizer 15. The different positions for the polarizers as external polarizers (FIG. 3a) or internal polarizers (FIG. 3b) are depicted. The polarisation state of light in a LCD panel is usually controlled by two external polarisers, placed outside the substrate glass. It is well known that placing the polarisers inside the substrates has many advantages, such as reduced display thickness, improved robustness and the possibility to use of birefringent plastic substrates; however, internal polarizers are more difficult to manufacture.

FIG. 3c and FIG. 3d show the combination of an internal “clean-up” polarizer 16 with two external polarizers 8 and 15. The internal polarizer reduces the depolarization that is caused by scattering of light in the color filters or on the pixel electrodes (Jones et al. US006124907). The overall contrast of the display can be substantially improved even for a clean-up polarizer with relatively low extinction ratio. In FIG. 3c, the clean-up polarizer is located between the color filters 13 and the common electrode 12, and has its transmission axis oriented parallel to the top polarizer 15. Light incident on the internal polarizer is partially transmitted or blocked according to its final polarisation state at the exit polariser, so less depolarisation can occur. In FIG. 3d, the clean-up polarizer is located in the plane of the pixel electrodes 10 with its transmission axis oriented parallel to the bottom polarizer 8, so the depolarized light is blocked by the clean-up polarizer.

The use of wire grid polarizers in liquid crystal displays has been considered for more than 20 years, for example by Grinberg (U.S. Pat. No. 4,688,897, 1985), where the wire grid serves as polarizer, reflector and pixel electrode in a reflective LCD. More recently, Sergan (J. Opt. Soc. Am. 19, 1872, 2002) used reflective wire grid polarizers in a twisted nematic LCD. Lee et al. demonstrated a stereoscopic LC display based on patterned wire grid polarizers (SID paper 8.4 2006). Ge et al. developed a transflective LCD (Appl. Phys. Lett. 92, 051109, 2008) and demonstrated light “recycling” from the LCD backlight (Appl. Phys. Lett. 93, 121104, 2008) both using the reflections from a wire grid.

Reflections from wire grid polarizers will cause two problems in LCD products: firstly, reflection of ambient light from the front of the display and secondly, selective reflection.

In the configuration where the wire grid polarizer is utilized as a clean-up polarizer 16 on the upper substrate next to the color filters 13 as shown in FIG. 4a, the reflected polarization direction of s-polarized ambient light is attenuated by the external iodine polarizer 15 and only a very small fraction 17 can leave the display (˜0.3%). The selective reflection 18 is also shown in FIG. 4a. It refers to the reflection from dark pixels 11a back towards the backlight 7 where it is reflected and then exits through bright pixels 11b to the observer, leading to locally increased brightness. The localized brightness variations may require correction by image processing.

If the wire grid clean-up polarizer 16 is located in the pixel electrode plane, as shown in FIG. 4b, or if the first polarizer 8 is replaced with a reflecting polarizer 8*, as in FIG. 4c, the ambient light reflected from the wire grid polarizer 16 is polarized in the direction that is parallel to the transmission axis of the second polarizer 15 and exits the display as 20 and 22. This is most pronounced in the dark state of the display. The absorption of the light when it traverses twice through the display components limits the effect to about 2% ambient light reflection, which, however, still causes noticeable contrast reduction under high ambient light conditions.

The mirror-like appearance with strong reflection of ambient light prevents the use of a wire grid polarizer as the second polarizer 15* as shown in FIG. 4c, which has near 90% s-polarized reflectivity 21 and between 10-20% p-polarized reflectivity 19.

Therefore, wire grid polarizers that combine the thickness and robustness advantages with absorbing rather than reflecting optical properties are highly desirable.

The problem of ambient light reflection for a LCD device that employs a wire grid polarizer has been addressed in (Sugita US2008/00904547). Absorbing layers on one or both of the surfaces of a conventional wire grid polarizer were provided, removing the ambient light reflection (Sugita US2008/00904547). The absorbing layer is described as a) a composite multilayer stack of alternating dielectric and metal layers or b) a coating type polarization layer. The composite dielectric/metal stack (e.g. ZrO₂ and Mo) requires coating in several successive steps which is time consuming and expensive. The etch step that transfers the pattern of a mold into the multilayer film and the metal that comprises the wire grid polarizer via a resist mask, requires isotropic etching through the plurality of layers of different materials. This is considered difficult since the suggested materials require different etch conditions.

The alternative coating type, absorbing layer, described in US2008/00904547, forms a uniform coating on top of the wire grid surface. The polarizing properties of the coating are generated by aligning a “suitable liquid” and structural fixation of the anisotropy. The alignment of the liquid is achieved by application of uniaxial stress or using the wire grid surface as alignment layer. US2008/00904547 does not further specify this “suitable liquid”. A third option in US2008/00904547 for the light absorbing layer that is coated onto the wire grid is an “absorbing wire layer”, using a material that is black (absorbs well in the visible wavelength range), e.g. carbon black, and patterned according to the metal wires of the wire grid. The material only requires a degree of polarization that provides sufficient reflective contrast by absorbing the polarization direction that would otherwise be reflected by the wire grid. All methods described in US2008/00904547 require additional layers to be coated onto the wire grid to achieve absorbing properties.

U.S. Pat. No. 6,251,297 proposes a method for manufacturing a resonant absorbing polarizer for the field of optical communication. The polarizer is based on a plurality of layered metal bars, which have a major axis length shorter than the wavelength of the incident light. This limited length is important for the resonant absorbing effect to occur; U.S. Pat. No. 6,251,297 remarks “. . . a grid type polarizing plate . . . totally differs in structure and operation from the polarizing plate to which the present invention is directed”.

Aligned suspensions of conducting, elongated particles (silver halide in stretched glass) have been demonstrated by Araujo (U.S. Pat. No. 3,540,793, 1970) and Komuro (U.S. Pat. No. 6,251,297, 1998). However, it is difficult to obtain sufficient alignment to give efficient polarization. Moreover, the presented structures have only small shape anisotropy; they are spheroids rather than wires.

Wire grid polarizers with tapered cross sections have been proposed in U.S. Pat. No. 7,046,442 (Suganuma, 2006). These shapes prevent the interference from the two metal/dielectric interfaces and, therefore, extend the wavelength range over which the wire grid polarizer shows high extinction ratio towards shorter wavelength. Specifically, U.S. Pat. No. 7,046,442 proposed triangular and staircase-like cross sections of the metal wires. The structures are preferably intended for beam splitter application, where the polarization directions are separated by transmission and reflection. Although the proposed tapered structures resemble shapes that are also useful for absorbing polarizers in the present invention, potential absorbing properties are not described in U.S. Pat. No. 7,046,442.

U.S. Pat. No. 7,227,684 B2 describes a reflecting polarizer that uses combined metallic and dielectric compounds adjacent to each other. The metal structure has a long and a short surface and covers the dielectric partially, similar to the T- or L-shaped absorbing/reflecting polarizer in the present invention. However, U.S. Pat. No. 7,227,684 B2 does not mention any absorbing effects of the wire grid polarizer. The structure in U.S. Pat. No. 7,227,684 B2 generates resonance effects, which can be tuned for maximum transmission or reflection at specific wavelength to form, e.g. narrow band filters.

Low-fill factor wire grid polarizers are proposed in U.S. Pat. No. 7,414,784B2, using a metal wire to period width of 0.18≦w/p≦0.25. This metal fraction range is optimized for application of the wire grid polarizer for light recycling in a LCD, which requires high transmission but also sufficient reflection. Even smaller fill factors, which would cause the wire grid polarizer to become absorbing and, therefore, useless for light recycling, are not covered in U.S. Pat. No. 714,784 B2.

Competition to wire grid polarizers for high performance in-cell polarizers for LCDs comes from lyotropic materials (Khan SID paper 46.4, 2004; Yoneyama US2006/0182902) and dyed smectic polymerised liquid crystals (Peeters Adv. Mat. 18, 2412, 2006, Lub WO2005/045485). Although these materials show excellent optical performance as polarizing elements, they are difficult to align over large areas as required for display application. Furthermore, the incorporated anisotropic dyes are organic substances that degrade at elevated temperature as those they would need to endure in subsequent manufacturing steps for a LCD panel.

In summary, there are applications where the small thickness and high durability of a wire grid polarizer would be very beneficial; however the reflecting properties of the wire grid are disturbing to the application, as for example in a liquid crystal display where ambient light reflections are problematic. Therefore, wire grid polarizers with at least one absorbing side are required. To date, no single-layer, intrinsically absorbing wire grid polarizer has been proposed or demonstrated.

### SUMMARY OF THE INVENTION

According to the present invention, a thick (>0.2 μm) wire grid with a small (e.g. ˜5%) fraction of metal behaves as an absorbing polarizer. In another aspect of this invention, a polarizer, which is absorbing from one side and reflecting from the other, can be made by grading the fraction of metal through the thickness.

An aspect of the present invention is based on reducing the surface reflections of the wire grid polarizer by reducing the fraction of metal that is exposed at the interface. The reflectivity of a surface depends on the refractive indices n₀ and n₁ of the two materials that meet. For normal incidence light, the Fresnel reflection R is:

$$R = {( \frac{{n}_{1} - {n}_{0}}{{n}_{1} + {n}_{0}} )}^{2} \qquad Equation 1$$

Here, n₀ is the refractive index of a dielectric in which the wire grid polarizer is embedded, and n₁ is the complex refractive index of the wire material:

n=a+iβ Equation 2

For metals, the complex refractive index is large, e.g. for Aluminum at 550 nm wavelength n_{Al}=0.958+i6.69 (from: Palik, “Handbook of Optical Constants of Solids” Academic Press Inc. London). Therefore, the Fresnel reflection is close to one; almost all the light is reflected and does not enter the bulk of the film.

Making an absorbing wire grid is based on reducing the large refractive index of the material, so that the light that is polarized in the direction parallel to the wires can enter the bulk and get absorbed, rather than reflected. The present invention includes two ways to achieve the lower refractive index:
1) Using a composite medium of a metal and a dielectric, with the metal only taking up a small fraction of the total volume, an effective refractive index is created, which can be tailored to achieve low reflectivity.
2) Using a wire material that combines sufficiently low reflectance with absorbing properties in the visible wavelength range. Structural anisotropy is introduced by shaping the material into nanometer-sized wires, which absorb the polarization along the wires and transmit the polarization perpendicular to the wires.

Both options for designing an absorbing wire grid polarizer may result in a polarizer of lower extinction ratio (ER=Tₚ/Tₛ) than a conventional wire grid made from metal with a volume fraction of ˜50%. However, for application where the polarizer is used in addition to an external polarizer, also a relatively low performance clean-up polarizer can substantially improve the total performance of the display. Furthermore, if the absorbing polarizer is used in connection with a conventional reflecting polarizer, a double-sided device can be made, that is absorbing from one side (to avoid ambient light reflections) and reflecting from the other side, which can be used for light recycling of the backlight.

An absorbing wire grid polarizer in accordance with the present invention enables efficient handling of ambient light reflection, which usually occurs with wire grid polarizers of the reflecting type. Absorbing wire grids combine the advantages of wire grids, which are thin, robust to chemicals and elevated processing temperatures, with the absorbing properties needed for applications where the reflection of the polarization direction which is not preferentially transmitted is undesired. Applications for absorbing wire grid polarizers include in-cell polarizers which are needed for contrast enhancement in LCDs and for highly integrated LCD systems where the backlight is incorporated into the panel. In both cases, a polarizer is needed which is absorbing from at least one side and which is thin and robust against solvents and high processing temperatures.

The approaches of using 1) a low metal fraction and 2) a conducting material with sufficiently low reflection can create a wire grid polarizer that is intrinsically absorbing, so a single layer can show the desired absorbing properties. This distinguishes the present invention from the previous idea of utilizing multilayer anti reflection films that are coated onto at least one side of a wire grid polarizer in US2008/00904547. The intrinsically absorbing wire grid polarizer requires fewer manufacturing steps than a multilayer deposition and etching of a single material is simpler than a combination of materials that require different etch conditions.

If the intrinsically absorbing wire grid is combined with a reflecting wire grid structure a polarizer with double-sided or graded absorption properties is facilitated. This enables applications where reflections from one side should be avoided but reflections from the other side are desired, e.g. for using the polarizer in a liquid crystal cell. The idea of a wire grid polarizer together with a light absorbing layer that faces the liquid crystal layer is described in US2008/00904547. The suggestion of using a wire grid polarizer for light recycling in a LCD is, however, well known and described in e.g. U.S. Pat. No. 714,784B2.

An aspect of the present invention concerns a modified wire profile that has low metal fraction on one side and higher metal fraction on the other side (changing gradually or in a step) to achieve absorbing properties on one of the sides, rather than an additional layer as in US2008/00904547. Alternatively, the present invention includes the combination of two wire grid polarizers consisting of different materials, one with high reflectivity (metal) and one with lower reflectivity that forms an absorbing polarizer. As the two wire grids both act as stand-alone polarizers, they can be in independent layers, can have different pitch and duty cycle and do not have to be aligned with one another, which gives additional design freedom. The advantage of using a material with lower reflectivity is that the required volume fractions of the material are larger and possibly easier to manufacture

Tapered wire profiles and L-shaped wire profiles were proposed to increase the broadband properties of the wire grid polarizer (U.S. Pat. No. 7,046,442) and to make narrow band filters (U.S. Pat. No. 7,227,684 B2), respectively. However, the absorbing and absorbing/reflecting double-sided properties were previously not discussed.

Wire grid polarizers generally have an advantage as in-cell polarizers over the competing dye doped polymerized liquid crystal polarizers, as the incorporated dyes are not temperature stable and the alignment of the dye molecules with the liquid crystal is often insufficient.

According to an aspect of the invention, a polarizer is provided having a wire grid including a plurality of wires aligned in parallel. From at least one side of the wire grid, the wire grid intrinsically mainly absorbs electromagnetic energy having a polarization direction parallel to the wires and mainly transmits electromagnetic energy having a polarization direction perpendicular to the wires.

In accordance with another aspect, the electromagnetic energy is visible light.

According to another aspect, the wires consist of metal and are embedded into a dielectric with the wires occupying only a fraction of the total volume of the polarizer so that the polarizer absorbs the electromagnetic energy having the polarization direction parallel to the wires.

According to still another aspect, a metal volume fraction is less than 10% metal by volume, the metal volume fraction representing the amount of metal to the total amount of dielectric and metal by volume.

According to yet another aspect, the metal volume fraction is within a range of 3% to 10% metal by volume.

In still another aspect, the wires are each made of a composite medium.

According to yet another aspect, a metal volume fraction of the composite medium is less than 10% metal by volume.

Regarding still another aspect, the metal volume fraction is within a range of 3% to 10% metal by volume.

As for another aspect, the wires exhibit a graded composition of metal and dielectric along a direction normal to a plane of the wire grid.

According to another aspect, the metal volume fraction of the wires at the at least one side is less than the metal volume fraction at a side opposite the at least one side.

In accordance with another aspect, the wires include at least one of carbon, graphite or carbon nanotubes individually or in composites, carbon-silver inks, molybdenum or tungsten compounds, silver oxide (individually or mixed with silver), metal nanoparticles that are dispersed in a lower refractive index medium, or organic conducting materials.

According to another aspect, a geometric profile of each of the wires varies in width from the at least one side to the side opposite the at least one side.

According to still another aspect, the width of the geometric profile at the at least one side is less than the width at the side opposite the at least one side.

In still another aspect, the geometric profile includes at least one of a graded structure, triangle, T-shape or L-shape.

According to another aspect of the invention, a combination polarizer is provided. The combination polarizer includes at least two polarizers as described herein and arranged in optical series.

According to still another aspect, the combination polarizer includes two of the polarizers, and the at least one sides of the respective wire grids face away from one another.

According to yet another aspect, a combination polarizer includes a first polarizer and a second polarizer arranged in optical series with the first polarizer. The second polarizer includes a wire grid including a plurality of wires aligned in parallel, wherein from at least one side of the wire grid, the wire grid intrinsically mainly reflects electromagnetic energy having a polarization direction parallel to the wires and mainly transmits electromagnetic energy having a polarization direction perpendicular to the wires.

According to another aspect, a liquid crystal display is provided. The liquid crystal display includes a liquid crystal cell formed between first and second substrates; and a polarizer as described herein arranged in optical series with the liquid crystal cell.

In yet another aspect, the polarizer is located within the liquid crystal cell.

According to yet another aspect, the display further includes an external polarizer operable in conjunction with the polarizer within the liquid crystal cell to improve contrast of the display.

According to another aspect, a method for fabricating a polarizer is provided. The method includes providing a high aspect ratio relief grating; and obliquely evaporating metal onto the relief grating to form L-shaped metal structures.

In accordance with another aspect, the method further includes removing the top metal layer.

According to another aspect, a method for fabricating a polarizer is provided which includes co-depositing at least two materials having different refractive indices on a substrate to form a film; and etching the film to form the plurality of wires.

According to yet another aspect, the co-depositing step includes keeping the deposition rates of the at least two materials generally constant to provide a homogeneous distribution throughout the film.

In accordance with still another aspect, the co-depositing step includes varying the deposition rates of the at least two materials to provide a graded distribution within the film.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic view of a conventional wire grid polarizer;

FIG. 2 represents the optical performance of a conventional wire grid polarizer;

FIG. 3 illustrates a) External polarizers in a conventional LCD, and b) in-cell polarizer in a conventional LCD;

FIG. 4 illustrates the problem of reflective polarizers in conventional LCDs with respect to a) ambient light reflection; b) selective reflection;

FIG. 5 illustrates examples a) and b) of a composite medium with an effective refractive index;

FIG. 6 is a graph representing the properties of a wire grid polarizer for different volume fractions of metal (reflectivity R, absorption A and transmission T for s-polarization calculated using an effective medium model and a FDTD simulation of a wire grid, respectively (Al in dielectric n=1.5, 50 nm period, 400 nm thickness, 550 nm wavelength);

FIG. 7 is a graph representing the properties of an absorbing wired grid polarizer based on graphite (100 nm period, 50 nm wired width, 550 nm wavelength, variable thickness);

FIG. 8 is a graph representing the properties of an absorbing wired grid polarizer based on graphite (100 nm period, 30 nm wired width, 550 nm wavelength, variable thickness);

FIG. 9 is a schematic illustration of a) an absorbing polarizer and b) graded, absorbing/reflecting polarizer, made up of a composition of material with higher and lower conductivity;

FIG. 10 is a cross section of double-sided absorbing/reflecting wire grid polarizer: a) triangular profile and b) T-profile;

FIG. 11 is a graph representing transmission and reflection of s-polarized light for a wire grid polarizer with triangular cross section (Al in dielectric n=1.5, 150 nm period, thickness 6 variable, 75 nm wired width 5 at base, 550 nm wavelength);

FIG. 12 is a graph representing transmission and reflection of p-polarized light for a wire grid polarizer with triangular cross section having the same parameters as in the wire grid polarizer of FIG. 11;

FIG. 13 is a graph representing transmission and reflection of s-polarized light for a wire grid polarizer with T-shaped cross section (Al in dielectric n=1.5, 150 nm period, thickness 33 100 nm, thickness 34 400 nm, 7.5-75 nm wired width 36, 7.5 nm wired width 35, 550 nm wavelength);

FIG. 14 is a graph representing transmission and reflection of p-polarized light for a wire grid polarizer with T-shaped cross section having the same parameters as in the wire grid polarizer of FIG. 13;

FIG. 15 is a graph representing optical performance of a wire grid polarizer with T-shaped cross section as a function of the thickness 34 of the vertical, low metal fraction component (other parameters same as in FIG. 13; T-shape pointing towards the source);

FIG. 16 illustrates example wire profiles of other possible graded structures for an absorbing/reflecting wire grid polarizer;

FIG. 17 illustrates an absorbing/reflecting polarizer as combination of two polarizers of absorbing and reflecting type, based on the material selection;

FIG. 18 illustrates an absorbing polarizer made by combination of two absorbing/reflecting polarizers with low metal fraction;

FIG. 19 illustrates a highly integrated LCD using wire grid polarizers inside the LC cell;

FIG. 20 represents a process for fabricating an absorbing/reflecting and absorbing wire grid polarizer by oblique evaporation;

FIG. 21 represents a process for fabricating an absorbing wire grid polarizer from a material with suitable refractive index by etching;

FIG. 22 represents a process for fabricating a composite material with tailored refractive index by co-deposition of two conducting materials with higher and lower refractive index; and

FIG. 23 represents a process for fabricating a wire grid polarizer by filling a moulded shape with metal from vapour phase or solution.

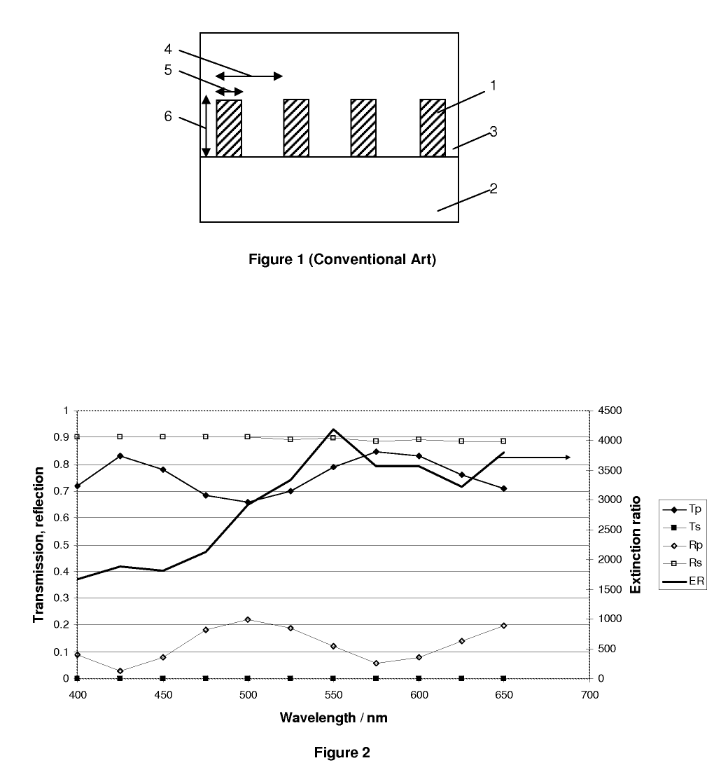

### DETAILED DESCRIPTION OF THE INVENTION

The present invention will now be described in detail with reference to the Figures, wherein like reference numerals are used to refer to like elements throughout.

### Embodiment 1

In a first embodiment of the invention, an absorbing wire grid polarizer is enabled by reducing the metal fraction. According to a simple model of the effective medium theory, the permittivity ε of a composite material consisting of parallel wires and dielectric for the direction of the electric field parallel to the wires is (Yeh, Opt. Comm. 26(3) 1978, 289-292):

ε_{eff}=fεₘ+(1−f)ε_{d} Equation 3

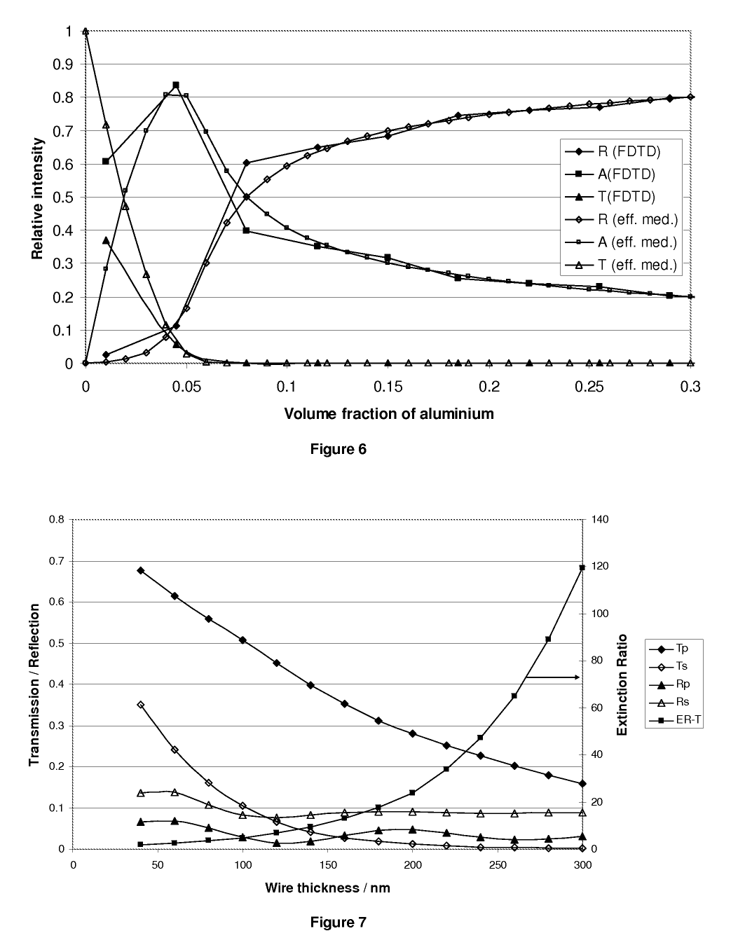

Here, εₘ and ε_{d} are the permittivities of the metal and the dielectric, respectively, with ε=n² (for materials with permeability μ=1). FIG. 5a and 5b show schematically two example composite media with the high refractive index material 24, 25 of low volume fraction in the dielectric matrix 2. The high refractive index material 24, which can have a variety of cross sectional profiles such as rectangular with width 5 and height 6, or circular high refractive index material 25 with diameter 26, extends continuously over the length 23, forming thin wires of periodicity 4. The graph in FIG. 6 shows the behavior of an aluminum wire grid polarizer depending on the metal volume fraction. Reflection R, absorption A and transmission T were calculated using the effective medium model (Equation 3), the Fresnel equation for normal incidence (Equation 1) and the Lambert-Beer's law of absorption. R, A and T were also simulated in the FDTD software for a wire grid structure of 50 nm period and 400 nm thickness at a wavelength of 550 nm. For metal volume fractions >10%, the polarizer shows low transmission, high reflection and medium absorption that reduces with increasing metal fraction. Wires with very small aluminum fraction (<0.4%) increasingly transmit Tₛ so the device stops working as a polarizer. However, in between the transparent and reflecting regime, there is a region where the reflections are still low but the absorption is at a maximum (A˜80%), so that Tₛ is sufficiently blocked. This demonstrates the principle for an absorbing wire grid polarizer based on low metal fraction wires.

The optimum metal volume fraction depends on the specific optical properties of different materials. In general, the optimum is expected in, but not limited to, the range between 3% to 10% metal by volume, when the surrounding material has a refractive index of about 1.5. For Aluminum in a material with n=1.5, the optimum volume fraction for low reflection is about 5%.

### Embodiment 2

In a second embodiment of the invention, an absorbing wire grid polarizer is proposed, which has wires made from a material that combines sufficiently low reflectance with absorbing properties in the visible wavelength range. Since the material forms nanometer-sized wire, the structural anisotropy enables selective absorption of the polarization direction parallel to the wires, whereas the polarization perpendicular to the wires is mostly transmitted.

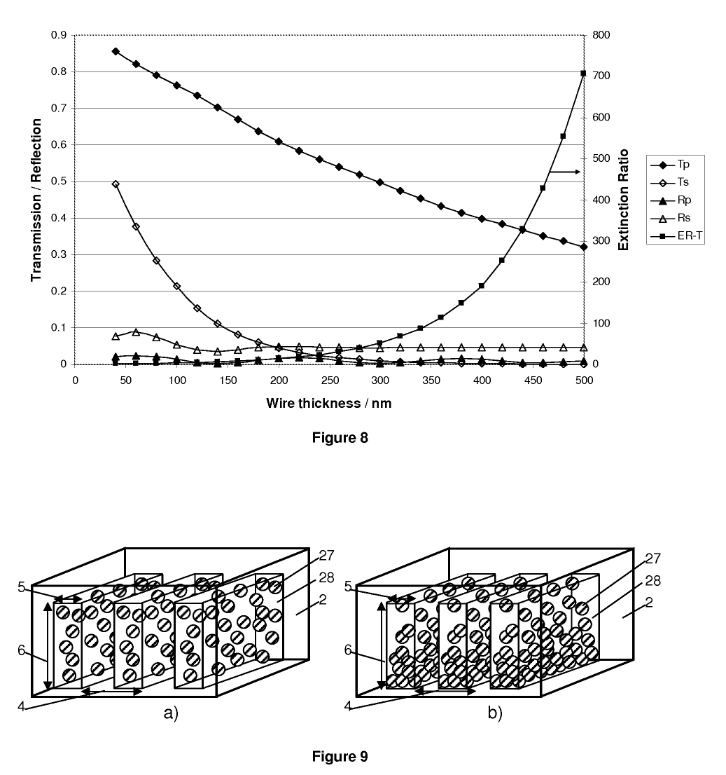

An example material is graphite, which is shown to enable an absorbing polarizer in FIG. 7 and FIG. 8. Here, a periodicity of p=100 nm and two different wire width w and a wavelength of 550 nm were chosen as an example. The reflectivity for s-polarized light is about 9% (w/p=0.5) and 5%, (w/p=0.3) respectively, depending on the chosen geometry. The extinction ratio and transmission of p-polarization strongly depend on the wire thickness, and a compromise needs to be found between them. Reducing the duty cycle w/p improves the performance, as with a smaller material thickness a better transmission and extinction ratio is achieved.

Materials that can be utilized to make this type of absorbing wire grid polarizers include, but are not limited to, carbon, graphite or carbon nanotubes individually or in composites (e.g. a polymer), carbon-silver inks, molybdenum or tungsten compounds, silver oxide (individually or mixed with silver), metal nanoparticles that are dispersed in a lower refractive index medium and organic conducting materials. The main requirements for a suitable material are that the combination of the real and imaginary part of the refractive index result in the desired low Fresnel reflections, but the imaginary part provides sufficient absorption in the visible wavelength range to attenuate the s-polarized component of the light. Transparent conducting materials, such as ITO, cannot serve as absorbing wire grid polarizers because there is no mechanism to attenuate the s-polarized component.

This embodiment includes a wire grid polarizer with a wire material, as shown in FIG. 9a, that consists of a composition of a material with higher 27 and material with lower refractive index 28, e.g. silver and silver oxide. The effective refractive index of the mixture can be varied between the indices of the pure substances. Silver oxide has black appearance and much lower reflectivity than silver, but shows good conductivity. In this arrangement, the conductive path within the mixture is not interrupted although the high index material 27 does not form individual wires but domains. The whole material mixture is structured into wires, forming a wire grid polarizer. It was previously shown that silver-silver oxide mixtures can be sputtered from pure silver targets by adjusting the oxygen flow (Barik et al., Thin Solid Films 429 (1-2), 2003, 129-134). A similar process can be used to fabricate either homogeneous silver-silver oxide mixture wires or graded composition wires, as shown in FIG. 9b, which can produce absorbing/reflecting polarizers, analogous to the structures described in Embodiment 3.

Again, the optimum metal volume fraction depends on the specific optical properties of different materials. In general, the optimum is expected in, but not limited to, the range between 3% to 10% metal by volume, when the surrounding material has a refractive index of about 1.5.

### Embodiment 3

This third embodiment is based on the absorbing wire grid polarizer in Embodiment 1, using low metal volume fractions to reduce the Rₛ surface reflections. Certain cross sections of the wires lead to a geometry where there is a low metal volume fraction on one side and a high metal volume fraction on the other side of the polarizer. For these geometries a double-sided polarizer is enabled that behaves differently when illuminated from one side or the other.

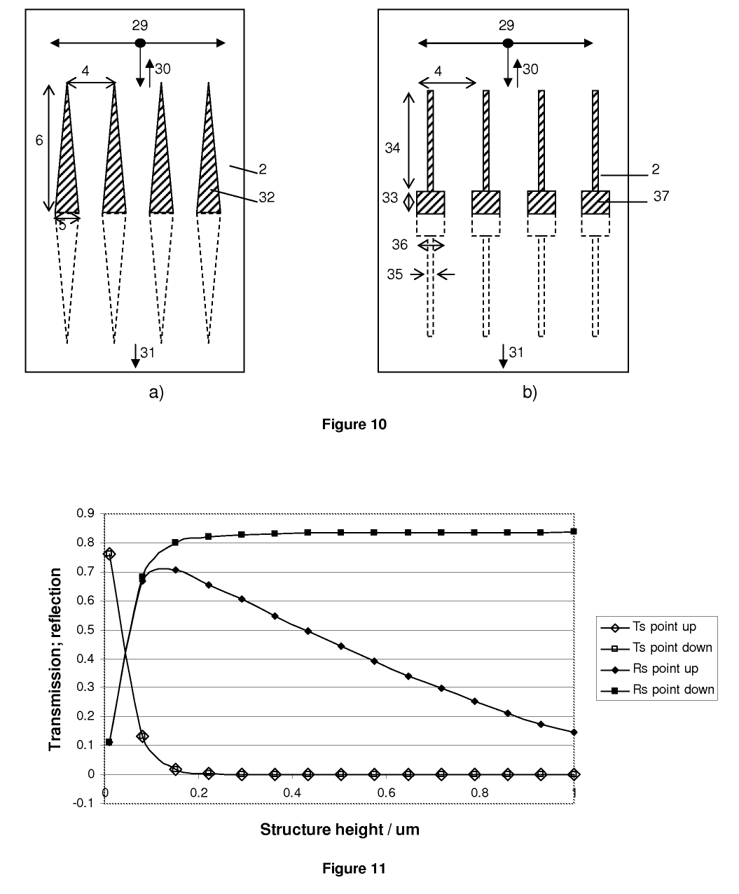

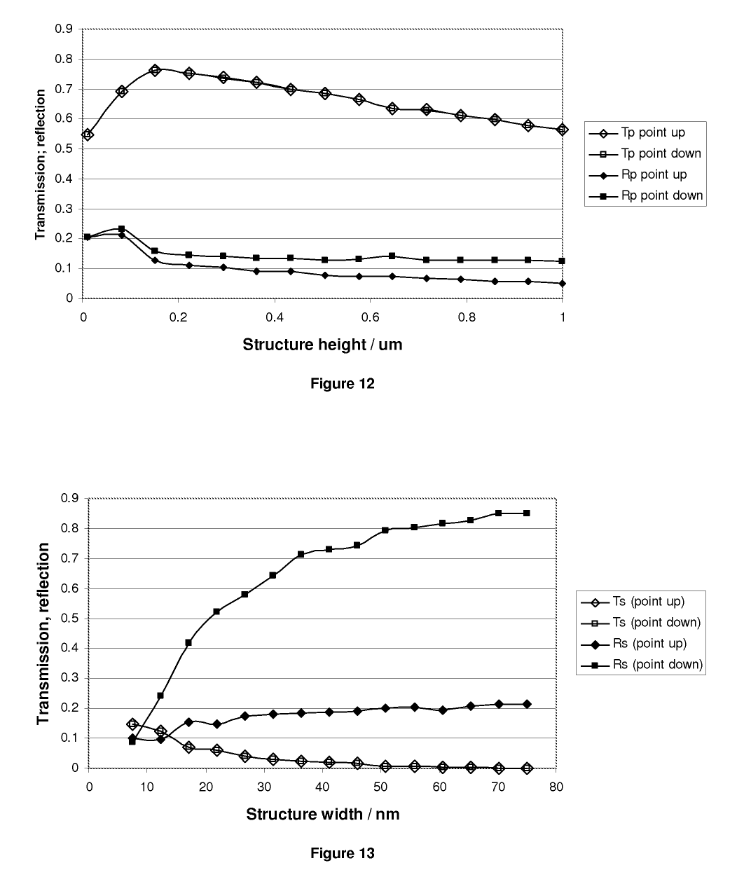

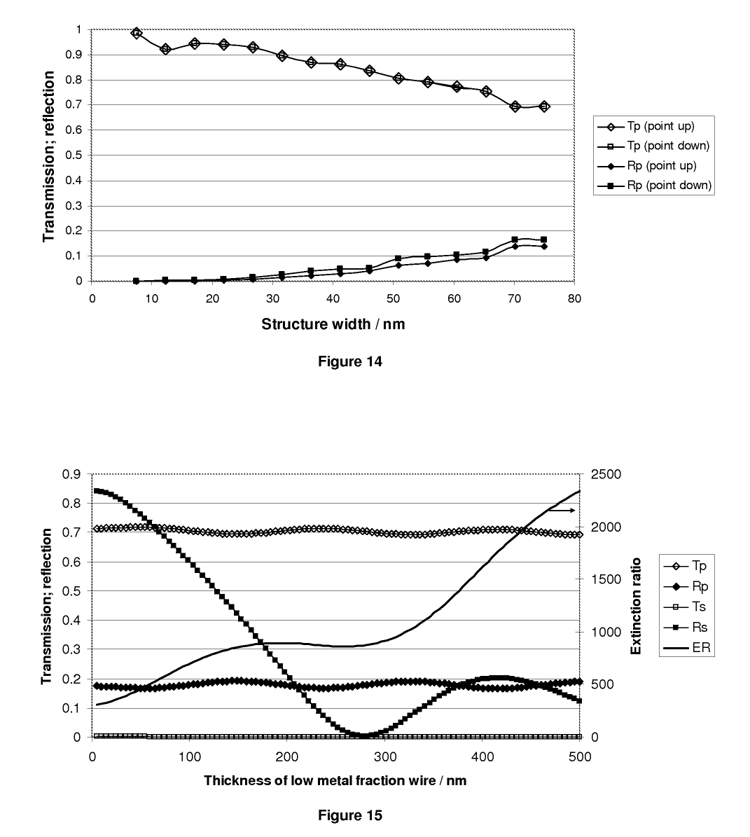

FIG. 10 shows an example of two wire profiles, a triangular 32 and a T-shaped one 37, which demonstrate absorbing/reflecting behavior. The schematic clarifies the geometry used for the simulation; the source location 29 remains static and the wire orientation is changed to point toward the source (solid outline of the structure) or away from the source (dashed outline of the structure). Transmission 31 and reflection 30 were simulated. FIG. 11 and FIG. 12 show the simulation results for the triangular profile wires 32 for s- and p-polarization, respectively. Both graphs contain the transmission and reflection data as a function of structure thickness for both orientations of the structures relative to the source (point up or point down). The triangular profile wires 32 are aluminum, embedded in a dielectric 2 with n=1.5; the periodicity 4 is set to 150 nm and the structure width 5 to 75 nm. FIG. 13 and FIG. 14 show the corresponding results for the T-shaped aluminum wires 37 with the geometry 150 nm period 4, 75 nm wire width on base of the T-shape 36 and 7.5-75 nm wire width on the top 35, 100 nm thickness of the base 33 and 400 nm thickness of the thin side 34.

The transmission of both polarization states is independent on the orientation (pointing up or down) of the two-sided structures. The triangular-shape structure gradually changes the metal fraction between top and bottom of the triangle. As the thickness of the triangular wires increases in FIG. 11, the s-polarization is differently reflected for the triangle pointing up or pointing down. For a thickness of about 900 nm, the s-polarization reflection is reduced to below 20% if the triangle points towards the light source. This is a very high aspect ratio structure; however, the T-shaped profile, which provides a step change in the metal fractions, is more efficient.

In FIG. 13, the total height of the structure is 500 nm. Depending on the width of the base, the reflectivity for s-polarized light can be increased to the desired value for the orientation where the base of the structure faces the source. For the opposite orientation, where the small metal fraction faces the source, the s-polarization reflectivity remains near 20%. FIG. 15 shows how the s-polarization reflection can be minimized by adjusting the thickness 34 of the vertical, low-metal fraction portion of the described T-shaped profile. For about 280 nm thickness 34 the reflectivity for the s-polarized light approaches zero, whereas the transmission and reflection for p-polarized light remains mostly constant. However, the thickness for which minimum reflection of s-polarized light occurs is wavelength dependent, so averaged over the visible spectrum a residual reflectivity is likely to remain.

The simulated geometries show that the optical performance of the absorbing/reflecting polarizer is currently lower than for a conventional reflecting wire grid polarizer. The design may be optimized, but depends on the application. A tradeoff between transmission, reflection and required extinction ration may be found by simulation.

The vertical, low metal fraction part of the absorbing reflecting wire grid polarizer 37 in FIG. 10 does not need to be aligned along the centre line of the base, but can also be displaced horizontally, forming an L-shape or similar. Furthermore, the vertical, low metal fraction part and the metal base may be an angle other than 90 degrees towards each other. FIG. 16 illustrates further example wire profiles and graded metal density arrangements that result in an absorbing/reflecting wire grid polarizer.

### Embodiment 4

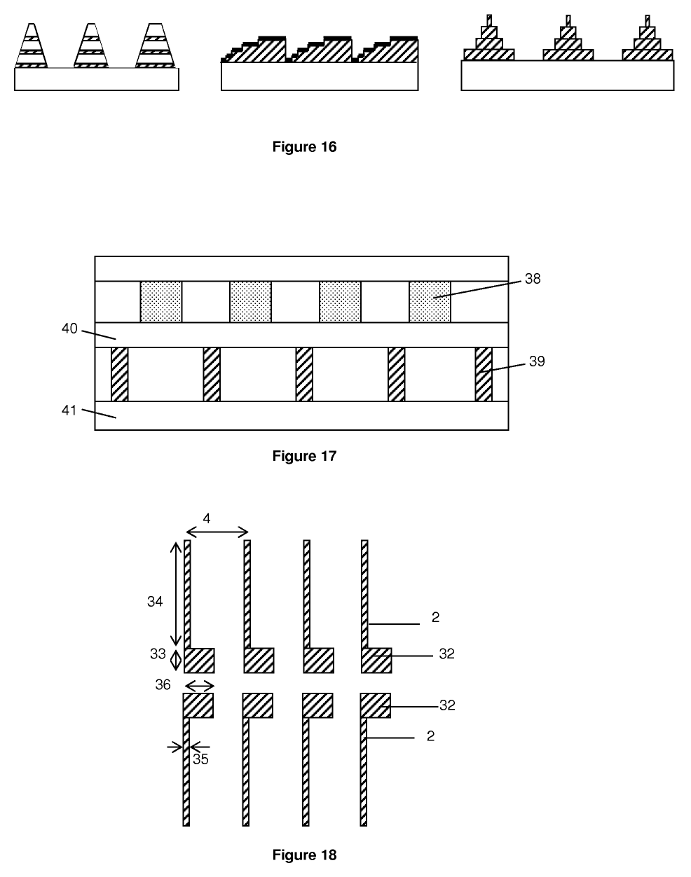

In analogy to the third embodiment, a fourth embodiment is proposed that provides an absorbing/reflecting wire grid polarizer. FIG. 17 shows an example arrangement, where a reflecting wire grid is combined with an absorbing wire grid, the optical properties of which are based on the chosen material rather than the geometry. The material based absorbing wire grid 38, as described in the second embodiment, is used in series with a conventional reflecting wire grid polarizer 39 and, therefore, the reflection of the s-polarized light can be reduced on one side of the arrangement only. Since the two polarizers are individual elements, they do not have to be aligned or have the same geometry as indicated in FIG. 17. This gives additional design freedom. However, this is not limiting; the two polarizers may be touching each other and have the same geometry so that they can be structured in a single manufacturing step.

### Embodiment 5

Two absorbing/reflecting polarizers as described in Embodiment 3 can be combined to form an absorbing polarizer of better extinction ratio than an absorbing polarizer that is solely based on a low metal fraction wire as in Embodiment 1. The combined arrangement is illustrated as an example in FIG. 18; it consists of two absorbing/reflecting wire grid polarizers that face each other with their reflecting sides.

### Embodiment 6

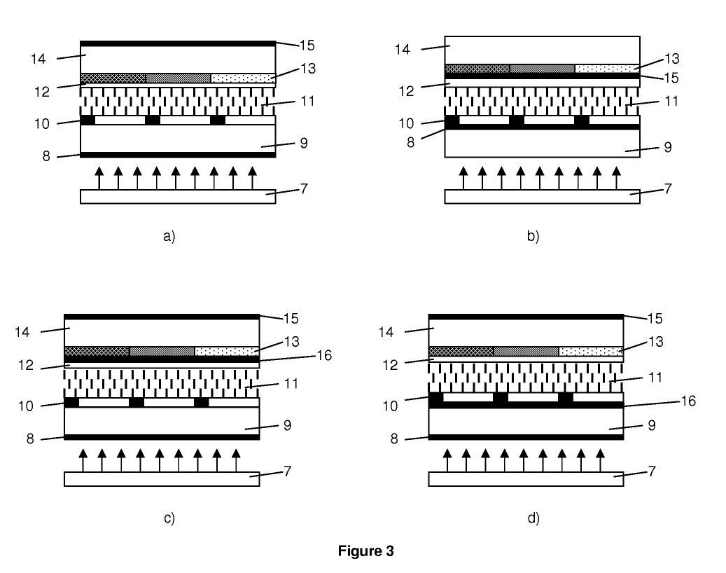

This embodiment is a specific application of the present invention to a liquid crystal display. The absorbing or absorbing/reflecting wire grid polarizer can be used as clean-up polarizer in connection with an additional external polarizer, as shown in FIGS. 3c and 3d. This reduces the depolarization by other display components and thus enhances the contrast of the LCD while the loss of contrast through additional reflections of ambient light is minimized. The position of the wire grid can be on the top substrate, the bottom substrate or both. The illustrated positions in FIG. 3c and 3d are preferred but not limiting. For the application of the two-sided absorbing/reflecting wire grid polarizer, as described in Embodiments 2 and 4, the absorbing side faces the external polarizer. If localized brightness variations should be avoided, an absorbing wire grid clean-up polarizer as in Embodiment 1, 3 or 5 can be used.

### Embodiment 7

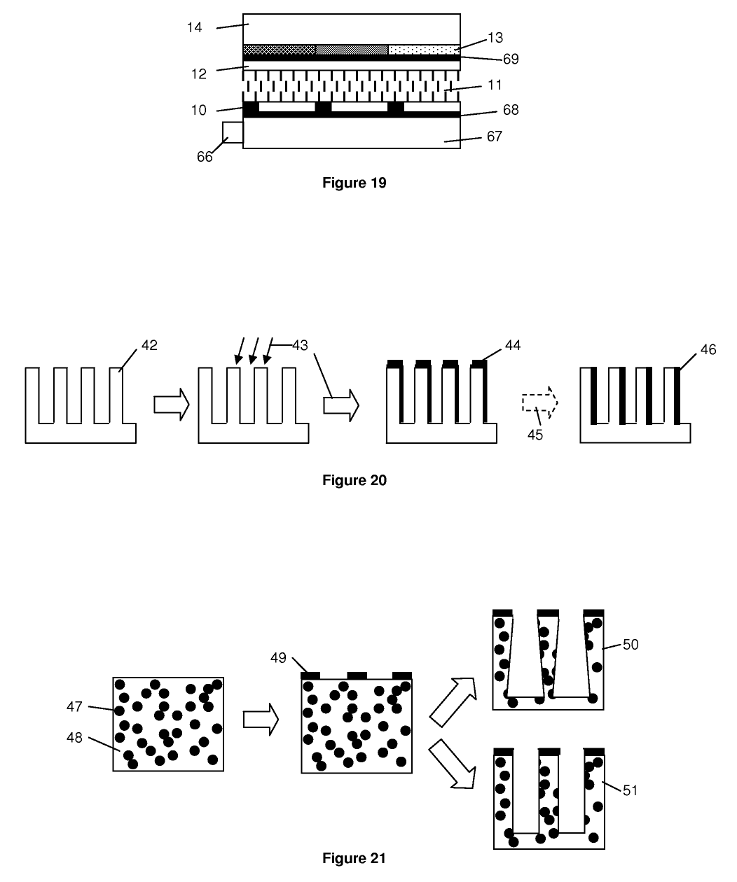

This embodiment is another specific application of the present invention to a liquid crystal display. For a highly integrated LCD, an example of which is shown in FIG. 19, a light source 66 is directly coupled into the lower substrate which serves as waveguide 67. To control the polarization direction that enters the LC cell and leaves the display, two-sided reflecting/absorbing wire grid polarizers 68, 69 can be integrated inside the LC cell. The position inside the LC cell for the polarizer 68 on the bottom substrate 67 is essential for the display to function. It can be combined with an external polarizer on the top substrate (not shown). The two-sided polarizer 69 is oriented with the absorbing side facing the observer and the reflecting side facing the waveguide 67. The waveguide unit 67 contains layers with scattering and reflecting properties. So the reflections back towards the waveguide unit can be harnessed as an advantage for light recycling without causing non-uniform light output.

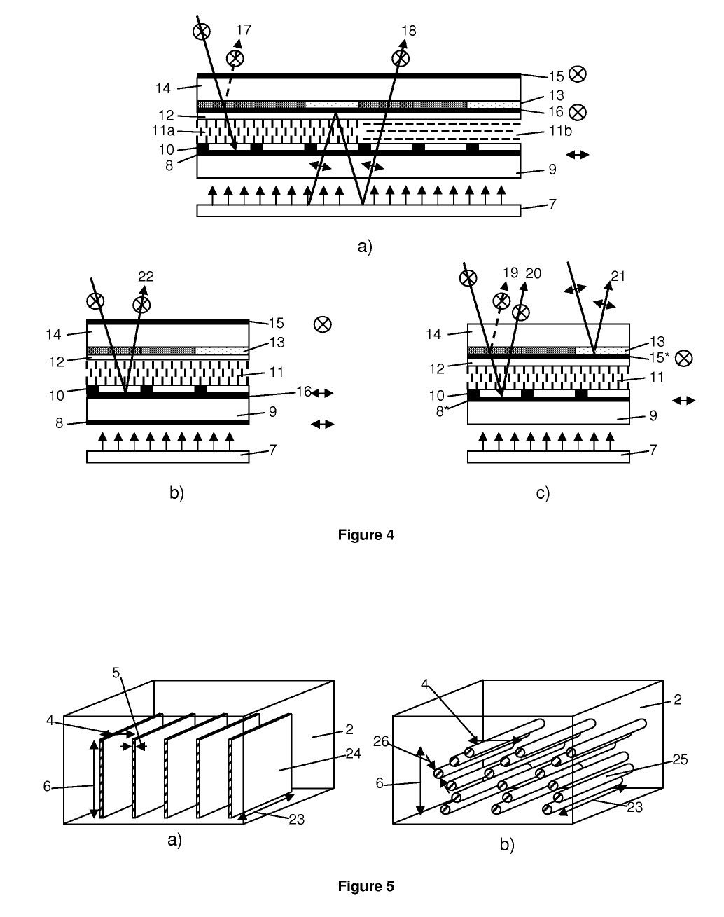

For high integration and maximum thickness reduction, also the top polarizer 69 is included inside the LC cell in FIG. 19. This polarizer 69 can be two-sided, with the absorbing side facing the observer, if the local brightness variations 18 in FIG. 4a are not important or corrected for. Otherwise the polarizer 69 may include two combined absorbing/reflecting polarizers with the absorbing sides pointing away from each other as in Embodiment 5.

The arrangement shown in FIG. 19 removes the problems due to ambient light reflections by using absorbing and absorbing/reflecting wire grid polarizers.

### Illustrative Fabrication

FIG. 20 shows a schematic for the fabrication by oblique evaporation of an absorbing/reflecting or absorbing polarizer as described in Embodiments 1 and 3. Onto a high aspect ratio relief grating 42, metal is obliquely evaporated 43, forming an absorbing/reflecting L-shaped structure 44. The top metal layer can be removed at 45 to form a purely absorbing wire grid polarizer 46.

In FIG. 21, the fabrication from a medium with lower reflectivity as described in embodiment 2 is shown. The material can be a composite of high 47 and lower 48 refractive index parts. The pattern of a high resolution mask 49 is transferred into the material. Depending on the etch conditions (isotropic or anisotropic) a square 51 or tapered 50 grating profile is formed.

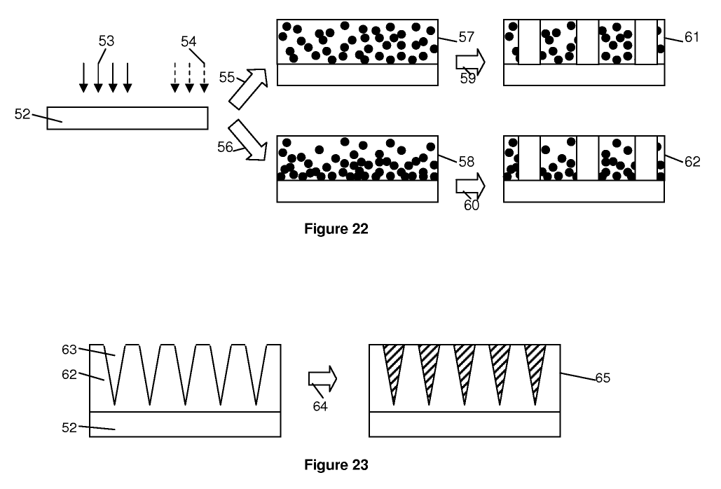

FIG. 22 illustrates the co-deposition of two materials 53 and 54, which have different optical properties, onto a substrate 52. By adjusting the deposition conditions, the volume fractions of the two materials throughout the film can be controlled. By keeping the deposition rates for both materials constant (55) a film with homogeneous distribution 57 forms. Varying the proportion of the rates (56) produces a graded distribution film 58. Etching with a high resolution mask forms the wires, which act as absorbing 60 or absorbing/reflecting polarizer 61.

Fabrication by material deposition into shaped moulds (e.g. triangular or step structures) is shown in FIG. 23. The mould 63 can be made into a suitable material 62 by e.g. an imprint process. The material deposition process can e.g. be from a vapor phase, a solution or from particles in dispersion. Sintering may be applied to densify the structures. Any layer build up on top across the whole substrate requires removal by e.g. etching.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A polarizer, comprising:
a wire grid including a plurality of wires aligned in parallel,
wherein from at least one side of the wire grid, the wire grid intrinsically mainly absorbs electromagnetic energy having a polarization direction parallel to the wires and mainly transmits electromagnetic energy having a polarization direction perpendicular to the wires.

2. The polarizer of claim 1, wherein the electromagnetic energy is visible light.

3. The polarizer of claim 1, wherein the wires consist of metal and are embedded into a dielectric with the wires occupying only a fraction of the total volume of the polarizer so that the polarizer absorbs the electromagnetic energy having the polarization direction parallel to the wires.

4. The polarizer of claim 3, wherein a metal volume fraction is less than 10%, the metal volume fraction representing the amount of metal to the total amount of dielectric and metal by volume.

5. The polarizer of claim 4, wherein the metal volume fraction is within a range of 3% to 10%.

6. The polarizer of claim 1, wherein the wires are each made of a composite medium.

7. The polarizer of claim 6, wherein the metal volume fraction of the composite medium is less than 10%.

8. The polarizer of claim 7, wherein the metal volume fraction is within a range of 3% to 10%.

9. The polarizer of claim 6, wherein the wires exhibit a graded composition of metal and dielectric along a direction normal to a plane of the wire grid.

10. The polarizer of claim 3, wherein the metal volume fraction of the wires at the at least one side is less than the metal volume fraction at a side opposite the at least one side.

11. The polarizer of claim 1 wherein the wires comprise at least one of carbon, graphite or carbon nanotubes individually or in composites, carbon-silver inks, molybdenum or tungsten compounds, silver oxide (individually or mixed with silver), metal nanoparticles that are dispersed in a lower refractive index medium, or organic conducting materials.

12. The polarizer of claim 1, wherein a geometric profile of each of the wires varies in width from the at least one side to the side opposite the at least one side.

13. The polarizer of claim 12, wherein the width of the geometric profile at the at least one side is less than the width at the side opposite the at least one side.

14. The polarizer of claim 12, wherein the geometric profile includes at least one of a graded structure, triangle, T-shape or L-shape.

15. A combination polarizer, comprising:
at least two polarizers according to claim 1, wherein the at least two polarizers are arranged in optical series.

16. The combination polarizer of claim 15, wherein the combination polarizer comprises two of the polarizers, and the at least one sides of the respective wire grids face away from one another.

17. A combination polarizer, comprising:
a first polarizer comprising a polarizer according to claim 1; and
a second polarizer arranged in optical series with the first polarizer, the second polarizer comprising a wire grid including a plurality of wires aligned in parallel, wherein from at least one side of the wire grid, the wire grid intrinsically mainly reflects electromagnetic energy having a polarization direction parallel to the wires and mainly transmits electromagnetic energy having a polarization direction perpendicular to the wires.

18. A liquid crystal display, comprising:
a liquid crystal cell formed between first and second substrates; and
a polarizer according to claim 1 arranged in optical series with the liquid crystal cell.

19. The display of claim 18, wherein the polarizer is located within the liquid crystal cell.

20. The display of claim 19, further comprising an external polarizer operable in conjunction with the polarizer within the liquid crystal cell to improve contrast of the display.

21. A method for fabricating a polarizer according to claim 1, comprising:
providing a high aspect ratio relief grating; and
obliquely evaporating metal onto the relief grating to form L-shaped metal structures.

22. The method of claim 21, further comprising removing the top metal layer.

23. A method for fabricating a polarizer according to claim 1, comprising:
co-depositing at least two materials having different refractive indices on a substrate to form a film; and
etching the film to form the plurality of wires.

24. The method of claim 23, wherein the co-depositing step comprises keeping the deposition rates of the at least two materials generally constant to provide a homogeneous distribution throughout the film.

25. The method of claim 23, wherein the co-depositing step comprises varying the deposition rates of the at least two materials to provide a graded distribution within the film.
